(19) United States
(12) Patent Application Publication
(10) Pub. No.: US 2026/0299399 A1
(43) Pub. Date: Oct. 1, 2026

(54) PHOTOMASK AND METHOD OF MANUFACTURING OR REPAIRING PHOTOMASK

(71) Applicant: Taiwan Semiconductor Manufacturing Company, Ltd., Hsinchu (TW)

(72) Inventors: Po-Ming HSU, Hsinchu (TW); Ming-Wei TSAI, Hsinchu (TW)

(73) Assignee: Taiwan Semiconductor Manufacturing Company, Ltd., Hsinchu (TW)

(21) Appl. No.: 19/093,465

(22) Filed: Mar. 28, 2025

(51) Int. Cl. G03F 1/32; G03F 1/38; G03F 1/60; G03F 1/72

(52) U.S. Cl. CPC G03F 1/32; G03F 1/38; G03F 1/60; G03F 1/72

(57) ABSTRACT

An embodiment method of manufacturing a photomask includes depositing a first lower insulation portion of a first insulation structure over a substrate in a vertical direction and forming a first light blocking structure over the first lower insulation portion in the vertical direction, where the first lower insulation portion is between the first light blocking structure and the substrate. The method further includes depositing a first upper insulation portion of the first insulation structure covering at least an upper surface of the first light blocking structure. The first insulation structure and the first light blocking structure constitute a first mask pattern structure. One or more characteristics of the first light blocking structure, the first lower insulation portion, and the first upper insulation portion are configured such that an overall light transmittance of the first mask pattern structure along the vertical direction ranges from 3% to 10%.

### BACKGROUND

Various processing steps are used to fabricate integrated circuit (IC) components on a semiconductor wafer. These steps include formation of one or more photoresist and/or hardmask patterns on the semiconductor wafer in conjunction with one or more deposition processes, removal processes, and cleaning processes. In some applications, photolithography is utilized to transfer a pattern from a photomask onto a semiconductor wafer. As the density of IC components in an IC chip increases, resolution enhancement techniques are developed to achieve a more precise pattern transfer onto the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A includes a simplified cross-sectional diagram of a first photomask example based on a binary mask (BIM) technology, an electrical field amplitude diagram, and a light intensity diagram, in accordance with some embodiments.

FIG. 1B includes a simplified cross-sectional diagram of a second photomask example based on a phase-shift mask (PSM) technology, an electrical field amplitude diagram, and a light intensity diagram, in accordance with some embodiments.

FIG. 1C includes a simplified cross-sectional diagram of a third photomask example based on an attenuated phase-shift mask (APSM) technology, an electrical field amplitude diagram, and a light intensity diagram, in accordance with some embodiments.

FIG. 2 is a diagram of various mask pattern structures of a photomask example, in accordance with some embodiments.

FIG. 3A is a top view of a portion of a photomask example, in accordance with some embodiments.

FIGS. 3B-3C are cross-sectional views of a portion of the photomask example in FIG. 3A, in accordance with some embodiments.

FIG. 3D is a cross-sectional view of a portion of another photomask example, in accordance with some embodiments.

FIGS. 4A-4C are cross-sectional views of structures at various stages of manufacturing a photomask, in accordance with some embodiments.

FIGS. 5A-5D are cross-sectional views of structures at various stages of repairing a photomask, in accordance with some embodiments.

FIGS. 6A-6C are top views of mask pattern structure examples based on various technology, in accordance with some embodiments.

FIGS. 7A-7B are cross-sectional views of a mask pattern structure example at different usage stages, in accordance with some embodiments.

FIGS. 7C-7D are cross-sectional views of another mask pattern structure example at different usage stages, in accordance with some embodiments.

FIGS. 8A-8C are perspective views of mask pattern structure examples based on variations of the example in FIGS. 3A-3C, in accordance with some embodiments.

FIG. 9 is a flowchart of a method of manufacturing a photomask, in accordance with some embodiments.

FIG. 10 is a flowchart of a method of repairing a photomask, in accordance with some embodiments.

FIG. 11 is a block diagram of an electronic design automation (EDA) system, in accordance with some embodiments.

FIG. 12 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

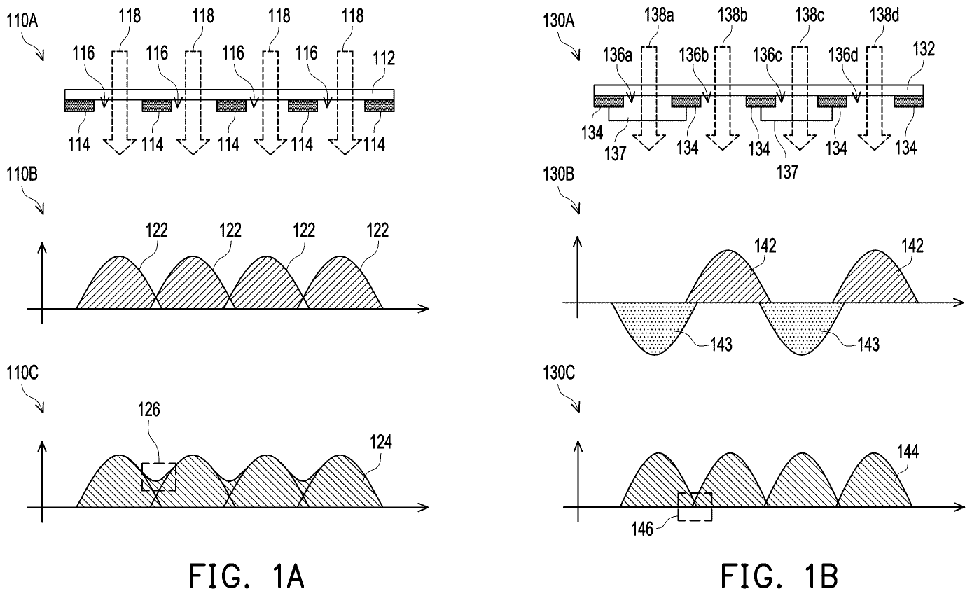

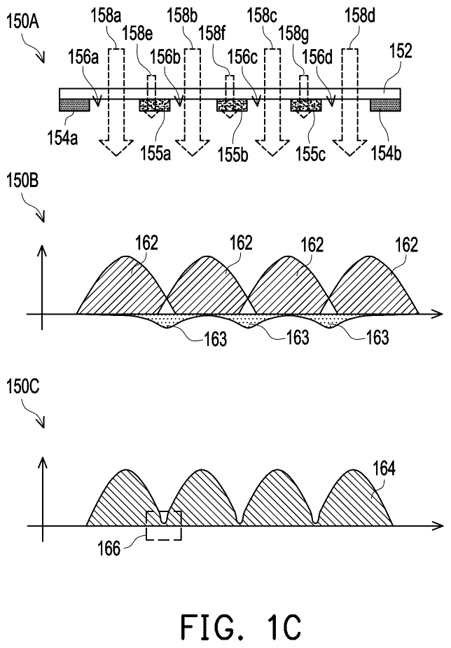

FIG. 1A includes a simplified cross-sectional diagram of a first photomask example 110A based on a binary mask (BIM) technology, an electrical field amplitude diagram 110B, and a light intensity diagram 110C, in accordance with some embodiments. In FIG. 1A, first photomask example 110A includes a substrate 112 and opaque structures 114. In some embodiments, substrate 112 has a high light transmittance (e.g., greater than 80%) within a light wavelength range used by a target lithographic process. In some embodiments, opaque structures 114 have a low light transmittance (e.g., less than 10%) within the light wavelength range used by the target lithographic process. In FIG. 1A, opaque structures 114 constitute mask pattern structures of first photomask example 110A, and the light-block regions of first photomask example 110A are defined based on the presence of opaque structures 114. In FIG. 1A, the light passing regions 116 are defined based on the absence of opaque structures 114.

In response to applying light (e.g., represented by arrows 118) to first photomask example 110A, the electrical field amplitude of the light reaching the wafer from each one of light passing regions 116 has a corresponding amplitude distribution 122. As shown in electrical field amplitude diagram 110B, each of amplitude distributions 122 has a peak at the position corresponding to the center of a corresponding light passing region 116 and gradually decreasing amplitude toward the positions corresponding to the edges of the light passing region 116.

The light intensity received at the wafer has a light intensity distribution 124, as shown in light intensity diagram 110C. In this example, as the light represented by amplitude distributions 122 are substantially in-phase, a region 126 where two amplitude distributions 122 corresponding to two adjacent light passing regions 116 will have a constructive superposition effect. As a result, the constructive superposition effect at region 126 causes the degradation of the sharpness of the transferred pattern on the wafer. As a result, the yield rate of the manufacturing process decreases as the minimum pattern size decreases, or the minimum pattern size increases in order to increase the target yield rate of the manufacturing process.

FIG. 1B includes a simplified cross-sectional diagram of a second photomask example 130A based on a phase-shift mask (PSM) technology, an electrical field amplitude diagram 130B, and a light intensity diagram 130C, in accordance with some embodiments. In FIG. 1B, second photomask example 130A includes a substrate 132 corresponding to substrate 112 in FIG. 1A and opaque structures 134 corresponding to opaque structures 114 in FIG. 1A. In FIG. 1B, opaque structures 134 constitute mask pattern structures of second photomask example 130A, and the light-block regions of first photomask example 110A are defined based on the presence of opaque structures 134. In FIG. 1B, the light passing regions 136a-136d are defined based on the absence of opaque structures 134. Moreover, phase shifting structures 137 are formed at a portion of the light passing regions in an alternating manner (e.g., in light passing regions 136a and 136c but not light passing regions 136b and 136d).

In response to applying light (e.g., represented by arrows 138a-138d) to second photomask example 130A, the electrical field amplitude of the light reaching the wafer from light passing regions 136b and 136d have corresponding amplitude distributions 142, and the electrical field amplitude of the light reaching the wafer from light passing regions 136a and 136c have corresponding amplitude distributions 143. As shown in electrical field amplitude diagram 130B, each one of amplitude distributions 142 and 143 has a peak at the position corresponding to the center of a corresponding light passing region 136a-136d and gradually decreasing amplitude toward the positions corresponding to the edges of the light passing region 136a-136d. In this example, amplitude distributions 142 and amplitude distributions 143 have opposite phases.

The light intensity received at the wafer has a light intensity distribution 144, as shown in light intensity diagram 130C. In this example, as the light represented by amplitude distributions 142 and 143 are substantially out-of-phase, a region 146 where one amplitude distribution 142 and one amplitude distribution 143 overlap will have a destructive interference effect. As a result, the destructive interference effect at region 146 causes the reduction of interferences between two adjacent light passing regions. Compared to first photomask example 110A, the sharpness of the transferred pattern on the wafer based on second photomask example 130A is improved. As a result, compared to first photomask example 110A under similar conditions, a lithographic process based on second photomask example 130A has an improved yield rate and/or a reduced minimum pattern size.

FIG. 1C includes a simplified cross-sectional diagram of a third photomask example 150A based on an attenuated phase-shift mask (APSM) technology, an electrical field amplitude diagram 150B, and a light intensity diagram 150C, in accordance with some embodiments. In FIG. 1C, third photomask example 150A includes a substrate 152 corresponding to substrate 112 in FIG. 1A, opaque structures 154a and 154b corresponding to opaque structures 114 in FIG. 1A, and partially transparent structures 155a, 155b, and 155c. In some embodiments, partially transparent structures 155a, 155b, and 155c have a low light transmittance (e.g., ranging from 3% to 10%) within a light wavelength range used by a target lithographic process, as well as a phase-shifting capability. In FIG. 1C, opaque structures 154a and 154b and partially transparent structures 155a, 155b, and 155c constitute mask pattern structures of third photomask example 150A. In FIG. 1C, the light-attenuating regions of third photomask example 150A are defined based on the presence of partially transparent structures 155a, 155b, and 155c. Also, a light passing region 156a is defined between opaque structure 154a and partially transparent structure 155a; a light passing region 156b is defined between partially transparent structures 155a and 155b; a light passing region 156c is defined between partially transparent structures 155b and 155c; and a light passing region 156d is defined between opaque structure 154b and partially transparent structure 155c.

In response to applying light (e.g., represented by arrows 158a-158g) to third photomask example 150A, the electrical field amplitude of the light reaching the wafer from each one of light passing regions 156a-156d has a corresponding amplitude distribution 162; and the electrical field amplitude of the light reaching the wafer from light-attenuating regions (through partially transparent structures 155a, 155b, and 155c) have corresponding amplitude distributions 163. As shown in electrical field amplitude diagram 150B, each of amplitude distributions 162 has a peak at the position corresponding to the center of a corresponding light passing region 156a-156d and gradually decreasing amplitude toward the positions corresponding to the edges of the light passing region 156a-156d. Also, each of amplitude distributions 163 has a peak at the position corresponding to the center of a corresponding partially transparent structure of the structures 155a, 155b, and 155c and gradually decreasing amplitude toward the positions corresponding to the edges of the corresponding partially transparent structure. In this example, amplitude distributions 162 and amplitude distributions 163 have opposite phases.

The light intensity received at the wafer has a light intensity distribution 164, as shown in light intensity diagram 150C. In this example, as the light represented by amplitude distributions 162 and 163 are substantially out-of-phase, a region 166 where adjacent amplitude distributions 162 and one amplitude distribution 163 overlap will have a destructive interference effect. As a result, the destructive interference effect at region 166 causes the reduction of superimposed light between two adjacent light passing regions. Compared to first photomask example 110A, the sharpness of the transferred pattern on the wafer based on third photomask example 150A is improved. As a result, compared to first photomask example 110A under similar conditions, a lithographic process based on second photomask example 150A has an improved yield rate and/or a reduced minimum pattern size.

In some embodiments, opaque structures 114 in FIG. 1A, opaque structures 134 in FIG. 1B, and opaque structures 154a/154b in FIG. 1C include ruthenium, ruthenium oxide, chromium, chromium oxide, and/or a molybdenum silicide compound with various molybdenum percentages. In some embodiments, partially transparent structures 155a, 155b, and 155c include a molybdenum silicide compound. In some embodiments, the materials used in opaque structures 114 in FIG. 1A have a resistivity ranging from 10Ω·m to 10⁵ Ω·m. In some embodiments, the materials used in opaque structures 134 in FIG. 1B and opaque structures 154a/154b in FIG. 1C have a resistivity ranging from 10⁵ Ω·m to 10¹¹ Ω·m.

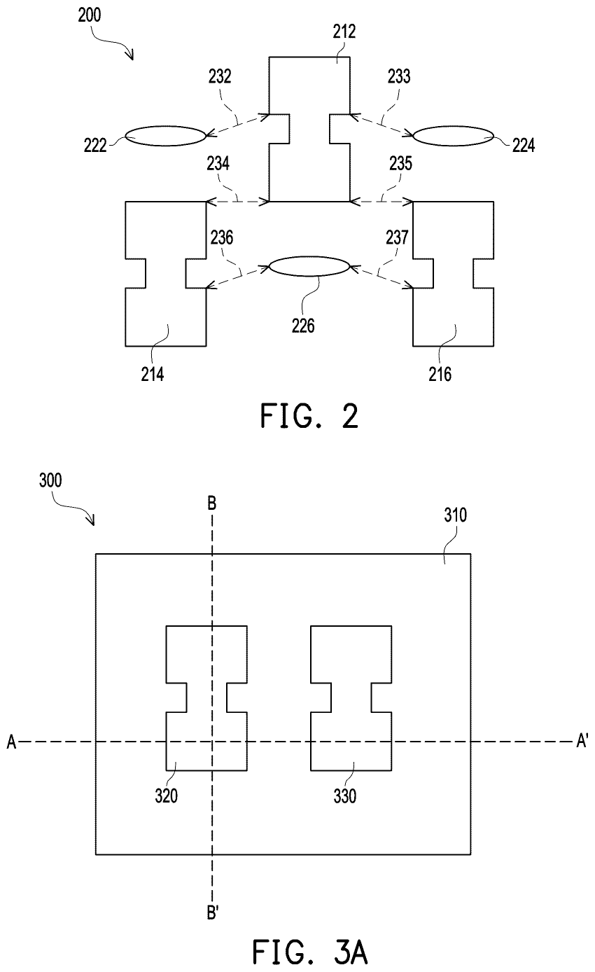

FIG. 2 is a diagram of various mask pattern structures of a photomask example 200, in accordance with some embodiments. FIG. 2 corresponds to a portion of all mask pattern structures of photomask example 200. In FIG. 2, photomask example 200 includes mask pattern structures 212, 214, 216, 222, 224, and 226. In some embodiments, mask pattern structures 212, 214, 216, 222, 224, and 226 are formed based on any of the examples in FIGS. 1A, 1B, and 1C.

In some embodiments, the distances between various mask pattern structures on photomask example 200 is less than 60 nanometers (nm). In some embodiments, during the handling and processing of photomask example 200, positive charges start to accumulate at the substrate (e.g., substrate 112, substrate 132, or substrate 152 in FIGS. 1A-1C) of photomask example 200 and negative charges start to accumulate at the mask pattern structures (e.g., mask pattern structures 212, 214, 216, 222, 224, and 226). As the electric field varies inversely with distance, the tips of the mask pattern structures are susceptible to electrostatic discharge (ESD) through discharge paths (e.g., paths 232, 233, 234, 235, 236, and 237). Therefore, the tips of mask pattern structures 212, 214, 216, 222, 224, and 226 are susceptible to decomposition, cornering, and/or deformation caused by electrostatic discharges. As a result, a photomask has a set lifetime based on estimated degradation caused by ESD. Also, the oxidation of mask pattern structures 212, 214, 216, 222, 224, and 226 also causes deformation thereof.

In some embodiments, by reducing the possibility of electrostatic discharges, the lifetime of a photomask is effectively extended. This may reduce the overall production costs and improve production yield. In some embodiments, by encapsulating a metal-based mask pattern by an insulation material, the charge accumulation at the metal-based mask pattern can be reduced, and the possibility of ESD can be therefore reduced. In some embodiments, the configuration according to the present application reduces or slows down the decomposition or deformation of the metal-based mask pattern caused by ESD or further oxidation. In some embodiments, the insulation material around the metal-based mask pattern also improves the phase-shift and transmittance of the resulting mask pattern structure and thus enhances the pattern rounding performance. As a result, the life of a resulting photomask is extended, and the yield of manufacturing based on the resulting photomask is increased.

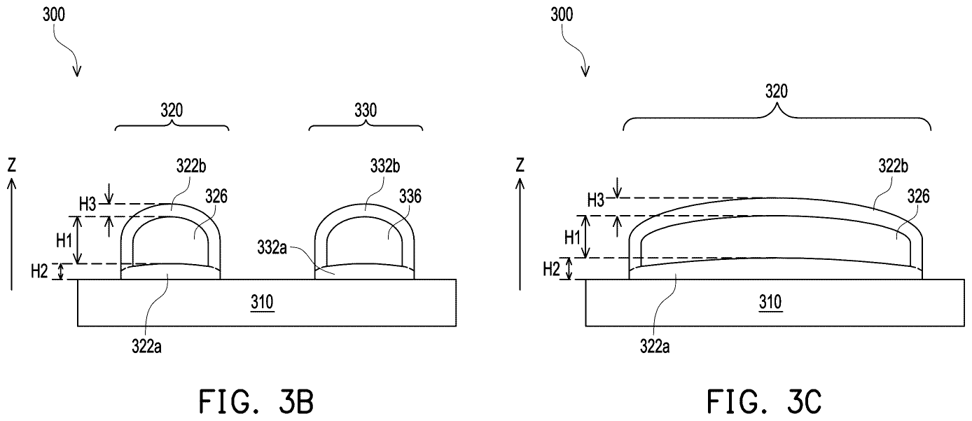

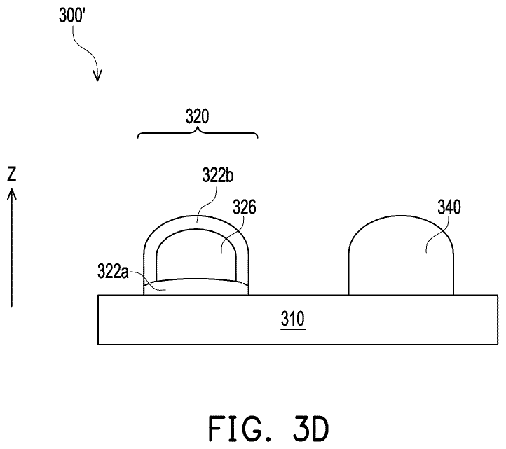

FIG. 3A is a top view of a portion of a photomask example 300, in accordance with some embodiments. FIG. 3A is a simplified top view of a portion of photomask example 300. In some embodiments, certain details are simplified or omitted in FIG. 3A.

In FIG. 3A, photomask example 300 includes a substrate 310 and two mask pattern structures 320 and 330. In some embodiments, substrate 310 includes a quartz glass. In some embodiments, mask pattern structures 320 and 330 are usable based on the APSM technology in FIG. 1C in place of partially transparent structures 155a, 155b, and 155c. As such, a photomask based on mask pattern structures 320 and 330 is also referred to as based on a modified APSM technology, or an APSM+ technology, in the present disclosure. FIG. 3B is a cross-sectional view of a portion of photomask example 300 along a reference line A-A′. Also, FIG. 3C is a cross-sectional view of a portion of photomask example 300 along a reference line B-B′ In FIGS. 3B-3C, photomask example 300 includes substrate 310 and mask pattern structures 320 and 330. Mask pattern structure 320 includes a lower insulation portion 322a and an upper insulation portion 322b of an insulation structure over substrate 310 in a vertical direction (e.g., the Z direction). Mask pattern structure 320 also includes a light blocking structure 326 over substrate 310 in the vertical direction. In FIGS. 3B-3C, lower insulation portion 322a is between light blocking structure 326 and substrate 310, and upper insulation portion 322b covers at least an upper surface of light blocking structure 326. In FIGS. 3B-3C, lower insulation portion 322a and upper insulation portion 322b are configured to cause encapsulation of light blocking structure 326 by the insulation structure (e.g., the combination of lower insulation portion 322a and upper insulation portion 322b). In some other embodiments, the combination of lower insulation portion 322a and upper insulation portion 322b does not cover the entirety of the sidewalls of light blocking structure 326. In some embodiments, an overall light transmittance of mask pattern structure 320 along the vertical direction ranges from 3% to 10%.

Moreover, in FIG. 3B, mask pattern structure 330 includes a lower insulation portion 332a and an upper insulation portion 332b of another insulation structure over substrate 310 in the vertical direction. Mask pattern structure 330 also includes a light blocking structure 336 over substrate 310 in the vertical direction. In FIG. 3B, lower insulation portion 332a is between light blocking structure 336 and substrate 310, and upper insulation portion 332b covers at least an upper surface of light blocking structure 336. In FIG. 3B, lower insulation portion 332a and upper insulation portion 332b are configured to encapsulate light blocking structure 336. In some other embodiments, the combination of lower insulation portion 332a and upper insulation portion 332b does not cover the entirety of the sidewalls of light blocking structure 336. In some embodiments, an overall light transmittance of mask pattern structure 330 along the vertical direction ranges from 3% to 10%.

Mask pattern structure 330 has a configuration the same or similar to that of mask pattern structure 320. In some embodiments, various features of mask pattern structure 330 have different thicknesses and shapes configured for having different light transmittance. In some embodiments, taking mask pattern structure 320 as an example, light blocking structure 326 includes a metal material, an oxide of the metal material, or a combination thereof. In some embodiments, the metal material includes chromium. In some embodiments, the insulation structures (e.g., lower insulation portion 322a, upper insulation portion 322b, lower insulation portion 332a, and/or upper insulation portion 332b) are formed based on silicon dioxide.

In some embodiments, taking mask pattern structure 320 as an example, light blocking structure 326 has a first thickness H1 along the vertical direction, and the thickness ranging from 40 nm to 80 nm. In some embodiments, lower insulation portion 322a has a second thickness H2 along the vertical direction, and upper insulation portion 322b has a third thickness H3 along the vertical direction. In some embodiments, a ratio of the first thickness H1 to a summation of the second thickness H2 and the third thickness H3 ranges from 6:1 to 3:1.

In a first example, based on H1+H2+H3 being 70 nm, and a ratio of H1: (H2+H3) is 6:1, an overall light transmittance of mask pattern structure 320 along the vertical direction is 3.7%. In a second example, based on H1+H2+H3 being 75 nm, and a ratio of H1: (H2+H3) is 4:1, an overall light transmittance of mask pattern structure 320 along the vertical direction is 5.6%. In a third example, based on H1+H2+H3 being 80 nm, and a ratio of H1: (H2+H3), an overall light transmittance of mask pattern structure 320 along the vertical direction is 7.9%. In some embodiments, the level of destructive interference effect as illustrated in FIG. 1C is configurable based on adjusting the light transmittance of mask pattern structures.

In FIG. 3B-3C, as a non-limiting example, all mask pattern structures of a photomask correspond to light blocking structures encapsulated by corresponding insulation structures based on the configuration of mask pattern structures 320 and 330. In some embodiments, a photomask includes at least one mask pattern structure based on the configuration of mask pattern structures 320 and 330 and at least one other mask pattern structure based on opaque structures 114 in FIG. 1A, opaque structures 134 in FIG. 1B, opaque structures 154a/154b in FIG. 1C, and/or partially transparent structures 155a, 155b, and 155c in FIG. 1C.

For example, FIG. 3D is a cross-sectional view of a portion of another photomask example 300′, in accordance with some embodiments. In some embodiments, photomask example 300′ is a variation of photomask example 300 and corresponds to a cross-sectional view taken at a reference line similar to reference line A-A′ in FIG. 3A. In FIG. 3D, components in FIG. 3D that are the same or similar to those in FIG. 3B are given the same reference numbers, and description thereof are simplified or omitted.

Compared to photomask example 300 in FIG. 3B, photomask example 300′ in FIG. 3D includes a mask pattern structure 340 in place of mask pattern structure 330. In some embodiments, photomask example 300′ is originally prepared based on any of the examples in FIG. 1A-1C. In some embodiments, all mask pattern structures originally formed in the photomask example 300′ (including mask pattern structure 340) correspond to opaque structures 114 in FIG. 1A, opaque structures 134 in FIG. 1B, opaque structures 154a/154bjn nj njnj in FIG. 1C, and/or partially transparent structures 155a, 155b, and 155c, and include a molybdenum silicide compound. During a repair operation, at least one damaged mask pattern structure is removed and replaced by mask pattern structure 320.

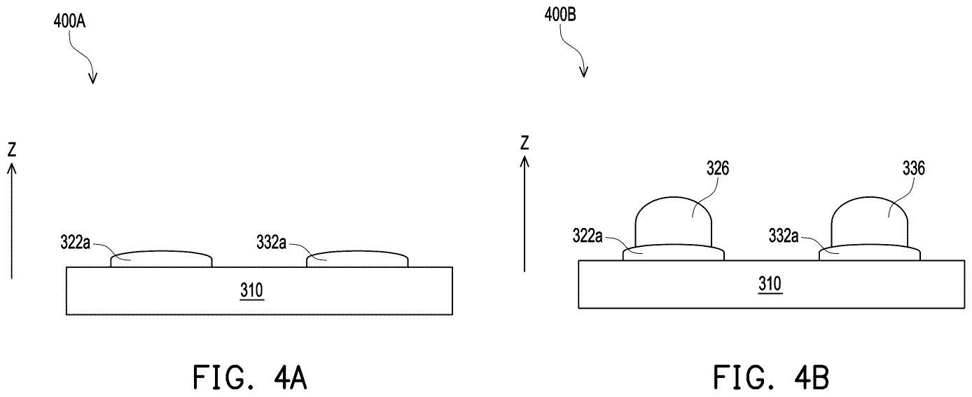

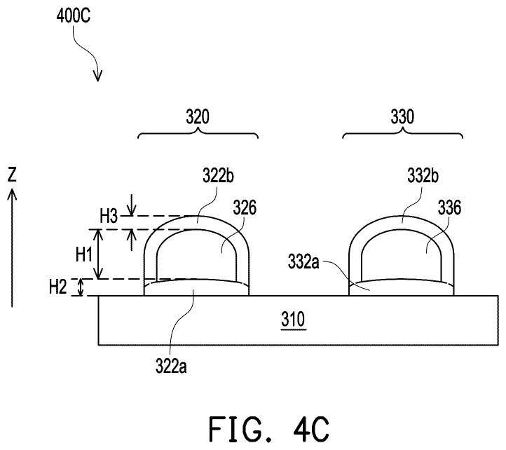

FIGS. 4A-4C are cross-sectional views of structures at various stages of manufacturing a photomask, in accordance with some embodiments. In some embodiments, the examples in FIGS. 4A-4C correspond to manufacturing of photomask example 300 in FIGS. 3A-3C. Components in FIGS. 4A-4C that are the same or similar to those in FIGS. 3A-3C are given the same reference numbers, and description thereof is simplified or omitted.

FIG. 4A is a cross-sectional view of a structure 400A that is formed based on depositing lower insulation portion 322a and lower insulation portion 332a over substrate 310 in a vertical direction (i.e., the Z direction). In some embodiments, lower insulation portion 322a and lower insulation portion 332a are formed based on depositing a layer of insulation material, and then patterning the deposited insulation material based on an etching process. In some embodiments, the layer of insulation material is deposited based on a chemical vapor deposition (CVD) process. In some embodiments, lower insulation portion 322a and lower insulation portion 332a include silicon dioxide. In some embodiments, substrate 310 includes a quartz glass.

FIG. 4B is a cross-sectional view of a structure 400B, which is formed based on structure 400A by forming light blocking structure 326 over lower insulation portion 322a and forming light blocking structure 336 over lower insulation portion 332a in the vertical direction. In FIG. 4B, lower insulation portion 322a is between light blocking structure 326 and substrate 310, and lower insulation portion 332a is between light blocking structure 336 and substrate 310. In some embodiments, forming the light blocking structure 326 or forming light blocking structure 336 includes forming light blocking structure 326 and/or light blocking structure 336 having a thickness along the vertical direction ranging from 40 nm to 80 nm.

In some embodiments, light blocking structures 326 and 336 are formed based on depositing a light-blocking material over lower insulation portions 322a and 332a, forming a patterned etch stop or hardmask material over the light-blocking material, etching the light-blocking material to become light blocking structures 326 and 336, and then removing the patterned etch stop or hardmask material. In some embodiments, the depositing the light-blocking material is based on spurting or electroplating. In some embodiments, light blocking structures 326 and 336 are formed based on a light-blocking material, which corresponds to a metal material, an oxide of the metal material, or a combination thereof. In some embodiments, the metal material of the light-blocking material includes chromium.

FIG. 4C is a cross-sectional view of a structure 400C, which is formed based on structure 400B by depositing upper insulation portion 322b covering at least an upper surface of light blocking structure 326 and depositing upper insulation portion 332b covering at least an upper surface of light blocking structure 336. In this non-limiting example, structure 400C corresponds to photomask example 300 in FIGS. 3A-3C. In this non-limiting example, lower insulation portion 322a, upper insulation portion 322b, and light blocking structure 326 constitute mask pattern structure 320; and lower insulation portion 332a, upper insulation portion 332b, and light blocking structure 336 constitute mask pattern structure 330. In some embodiments, upper insulation portion 322b and upper insulation portion 332b are formed based on depositing a second layer of insulation material, and then patterning the deposited insulation material based on an etching process. In some embodiments, the second layer of insulation material is deposited based on a CVD process. In some embodiments, upper insulation portion 322b and upper insulation portion 332b include silicon dioxide.

In some embodiments, one or more characteristics of light blocking structures 326/336, lower insulation portions 322a/332a, and upper insulation portions 322b/332b are configured such that an overall light transmittance of mask pattern structure 320 or mask pattern structure 330 along the vertical direction ranges from 3% to 10%. In some embodiments, the one or more characteristics correspond to configuring the thicknesses of various features. For example, light blocking structure 326 has a first thickness H1 along the vertical direction, lower insulation portion 322a has a second thickness H2 along the vertical direction, and upper insulation portion 322b has a third thickness H3 along the vertical direction. In some embodiments, a ratio of the first thickness to a summation of the second thickness and the third thickness ranges from 6:1 to 3:1.

In some embodiments, instead of forming mask pattern structure 330 having a configuration similar to that of mask pattern structure 320, mask pattern structure 340 is formed in place of mask pattern structure 330, as illustrated with reference to FIG. 3D. In some embodiments, mask pattern structure 340 is based on another light blocking structure that includes a molybdenum silicide compound.

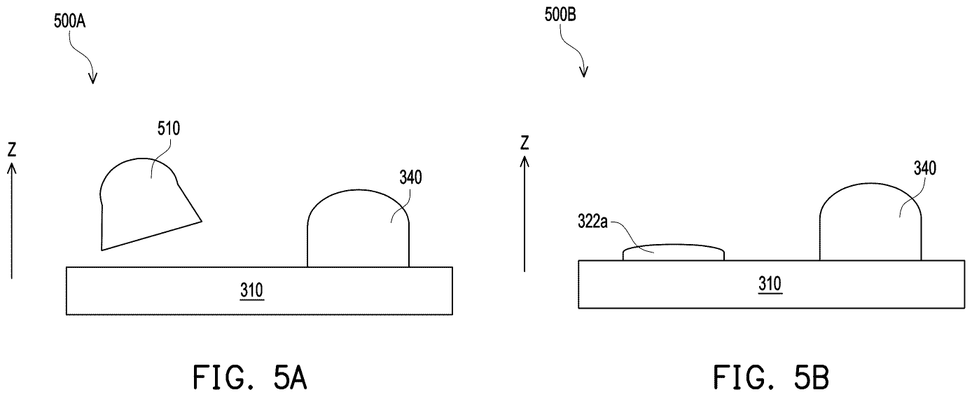

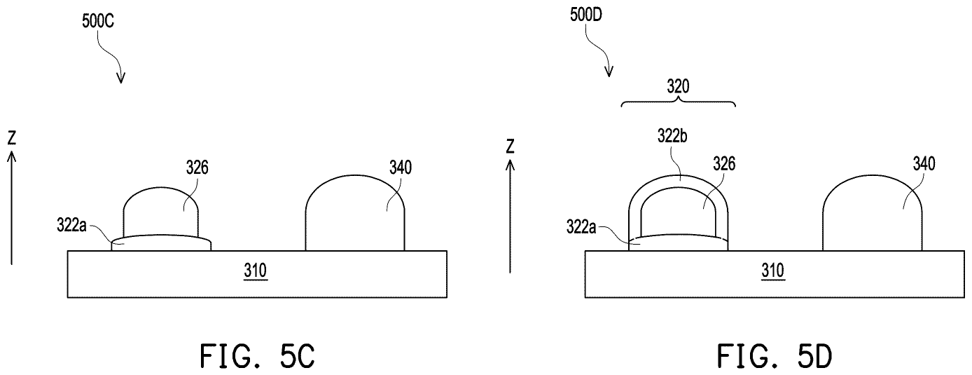

FIGS. 5A-5D are cross-sectional views of structures at various stages of repairing a photomask, in accordance with some embodiments. In some embodiments, the examples in FIGS. 5A-5D correspond to repairing a photomask by adding replacement mask pattern structures based on mask pattern structure 320 in photomask example 300′ in FIG. 3D. Components in FIGS. 5A-5D that are the same or similar to those in FIG. 3D are given the same reference numbers, and description thereof is simplified or omitted.

FIG. 5A is a cross-sectional view of a structure 500A that is formed based on removing a target mask pattern structure 510 from substrate 310. In some embodiments, target mask pattern structure 510 corresponding to a target mask pattern. In some embodiments, target mask pattern structure 510 has a configuration similar to that of mask pattern structure 340 as illustrated with reference to FIG. 3D, with additional damages and/or deformations caused by ESD from a certain number of handling and moving occurrences (e.g., 50,000 or more movement counts). In some embodiments, the mask structures that are still usable (e.g., mask pattern structure 340) are protected by a patterned etch stop or hardmask material before target mask pattern structure 510 is removed by an etching process.

FIG. 5B is a cross-sectional view of a structure 500B, which is formed based on structure 500A by depositing lower insulation portion 322a over substrate 310 in a vertical direction (i.e., the Z direction). In some embodiments, lower insulation portion 322a is formed in a manner similar to the formation of lower insulation portion 322a in the example of FIG. 4A. In some embodiments, lower insulation portion 322a includes silicon dioxide. In some embodiments, substrate 310 includes a quartz glass.

FIG. 5C is a cross-sectional view of a structure 500C, which is formed based on structure 500B by forming light blocking structure 326 over lower insulation portion 322a in the vertical direction. In FIG. 5C, lower insulation portion 322a is between light blocking structure 326 and substrate 310. In some embodiments, forming the light blocking structure 326 includes forming light blocking structure 326 having a thickness along the vertical direction ranging from 40 nm to 80 nm. In some embodiments, light blocking structure 326 is formed in a manner similar to the formation of light blocking structure 326 in the example of FIG. 4B. In some embodiments, light blocking structure 326 is formed based on a metal material, an oxide of the metal material, or a combination thereof. In some embodiments, the metal material includes chromium.

FIG. 5D is a cross-sectional view of a structure 500D, which is formed based on structure 500C by depositing upper insulation portion 322b covering at least an upper surface of light blocking structure 326. In this non-limiting example, structure 500D corresponds to photomask example 300′ in FIG. 3D. In this non-limiting example, lower insulation portion 322a, upper insulation portion 322b, and light blocking structure 326 constitute mask pattern structure 320. In some embodiments, upper insulation portion 322b is formed in a manner similar to the formation of upper insulation portion 322b in the example of FIG. 4C. In some embodiments, upper insulation portion 322b includes silicon dioxide.

In some embodiments, one or more characteristics of light blocking structure 326, lower insulation portion 322a, and upper insulation portion 322b are configured such that an overall light transmittance of mask pattern structure 320 along the vertical direction ranges from 3% to 10%. In some embodiments, the one or more characteristics correspond to configuring the thicknesses of various features as illustrated with reference to FIG. 3B and/or FIG. 4C. For example, light blocking structure 326 has a first thickness along the vertical direction, lower insulation portion 322a has a second thickness along the vertical direction, and upper insulation portion 322b has a third thickness along the vertical direction. In some embodiments, a ratio of the first thickness to a summation of the second thickness and the third thickness ranges from 6:1 to 3:1.

As a non-limiting example, FIGS. 5A-5D correspond to repairing a photomask with original mask pattern structures based on any of the examples in FIG. 1A-1C. In some embodiments, the repairing process illustrated with reference to FIGS. 5A-5D is also applicable to repairing a photomask with original mask pattern structures based on the examples of mask pattern structures 320 and 330 in FIGS. 3B and 3C.

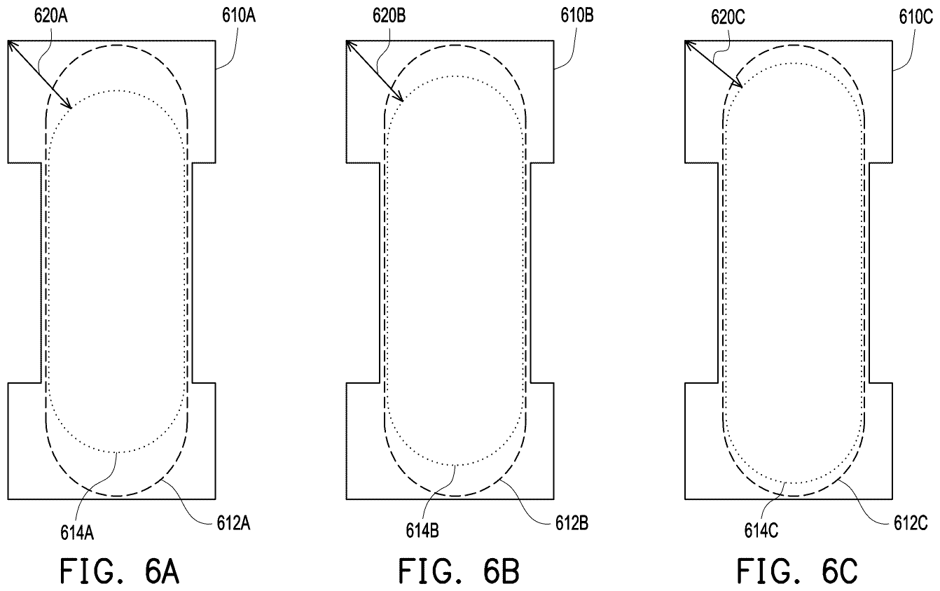

FIGS. 6A-6C are top views of mask pattern structure examples based on various technology, in accordance with some embodiments. For example, FIG. 6A includes a mask pattern structure 610A based on a PSM technology, such as the PSM technology illustrated with reference to FIG. 1B. FIG. 6B includes a mask pattern structure 610B based on an APSM technology, such as the APSM technology illustrated with reference to FIG. 1C. FIG. 6C includes a mask pattern structure 610C based on an APSM+technology, such as the APSM+technology illustrated with reference to FIGS. 3A-3C.

In this example, mask pattern structure 610A, mask pattern structure 610B, and mask pattern structure 610C have similar size and shape designed for forming target patterns 612A, 612B, and 612C on a wafer. In this non-limiting example, based on the deconstructive interference effects based on PSM, APSM, and APSM+, mask pattern structure 610A, mask pattern structure 610A, mask pattern structure 610B, and mask pattern structure 610C instead result in actual patterns 614A, 614B, and 614C on a wafer.

In FIG. 6A, mask pattern structure 610A has a corner edge placement error (EPE) 620A measuring the difference between a corner of the mask pattern structure 610A and the actual pattern 614A. In FIG. 6B, mask pattern structure 610B has a corner EPE 620B measuring the difference between a corner of the mask pattern structure 610B and the actual pattern 614B. In FIG. 6C, mask pattern structure 610C has a corner EPE 620C measuring the difference between a corner of the mask pattern structure 610C and the actual pattern 614C. In this non-limiting example, letting corner EPE 620A be X, corner EPE 620B ranges from 0.7 X to 0.8 X, and corner EPE 620C ranges from 0.5 X to 0.6 X. As a result, a mask pattern structure based on APSM+ (compared to PSM and APSM) improves the corner rounding or shortening issue.

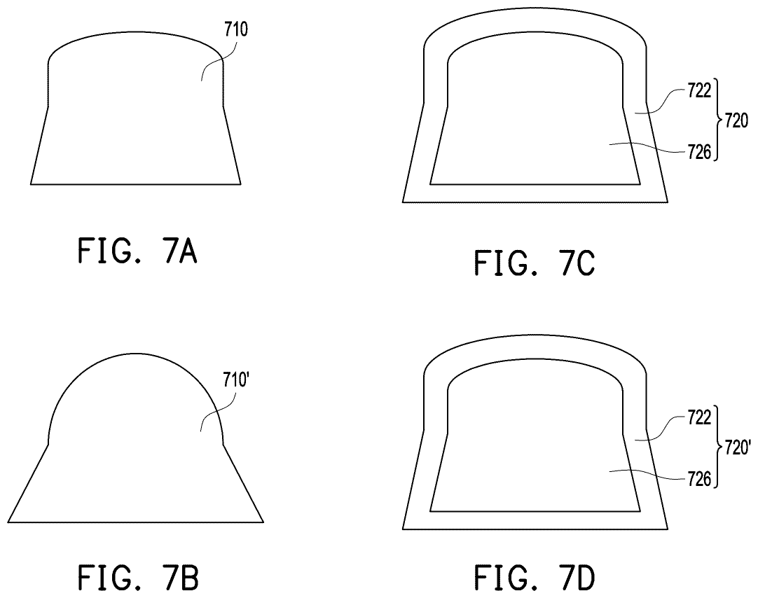

FIGS. 7A-7B are cross-sectional views of a mask pattern structure example at different usage stages, in accordance with some embodiments. FIG. 7A includes a cross-sectional view of a mask pattern structure 710 of a photomask based on a PSM technology, such as the PSM technology illustrated with reference to FIG. 1B, at a usage stage before any movement or handling of the photomask. FIG. 7B includes a cross-sectional view of a mask pattern structure 710′ of the photomask at a usage stage after 50,000 movement or handling counts. Compared to mask pattern structure 710, mask pattern structure 710′ exhibits significant degradation at upper corners.

FIGS. 7C-7D are cross-sectional views of another mask pattern structure example at different usage stages, in accordance with some embodiments. FIG. 7C includes a cross-sectional view of a mask pattern structure 720 of a photomask based on an APSM+technology, such as the APSM+technology illustrated with reference to FIGS. 3A-3C, at a usage stage before any movement or handling of the photomask. In FIG. 7C, mask pattern structure 720 includes an insulation structure 722 corresponding to the combination of lower insulation portion 322a and upper insulation portion 322b in FIGS. 3B-3C. In FIG. 7C, mask pattern structure 720 also includes a light blocking structure 726 corresponding to light blocking structure 326 in FIGS. 3B-3C.

Moreover, FIG. 7D includes a cross-sectional view of the mask pattern structure 720′ of the photomask at a usage stage after 50,000 movement or handling counts. Compared to mask pattern structure 720 in FIG. 7C, mask pattern structure 720′ exhibits no observable degradation.

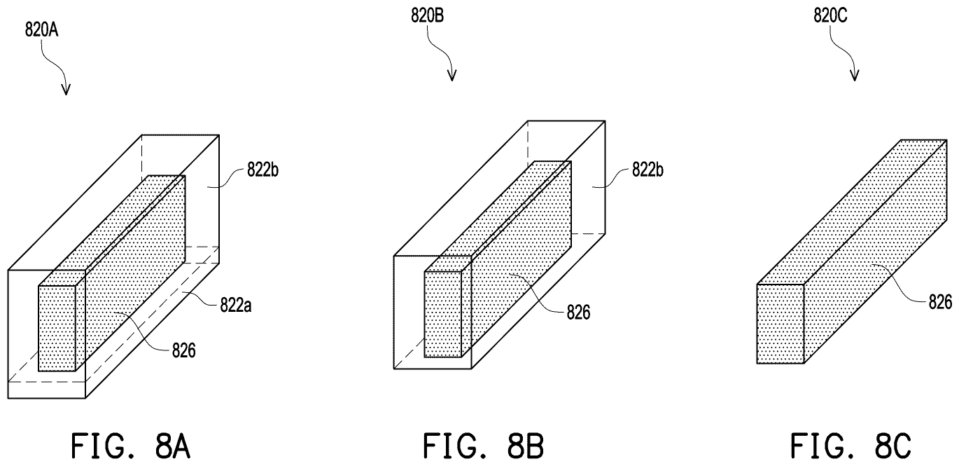

FIG. 8A is a perspective view of a mask pattern structure example 820A based on the example in FIGS. 3A-3C, in accordance with some embodiments. In FIG. 8A, mask pattern structure 820A includes a lower insulation portion 822a, an upper insulation portion 822b, and a light blocking structure 826 encapsulated by the combination of lower insulation portion 822a and upper insulation portion 822b. In some embodiments, lower insulation portion 822a corresponds to lower insulation portion 322a in FIGS. 3B-3C, upper insulation portion 822b corresponds to upper insulation portion 322b in FIGS. 3B-3C, and light blocking structure 826 corresponds to light blocking structure 326 in FIGS. 3B-3C.

FIG. 8B is a perspective view of a mask pattern structure example 820B, which is a variation of mask pattern structure 820A without lower insulation portion 822a. FIG. 8C is a perspective view of a mask pattern structure example 820C, which is a variation of mask pattern structure 820A without lower insulation portion 822a and without upper insulation portion 822b, In some embodiments, based on a simulation after 18,200 movement counts, mask pattern structure 820A has about 0% of deformation; mask pattern structure 820B has about 0% of deformation; and mask pattern structure 820C has about 3% of deformation. In some embodiments, based on a simulation after 73,000 movement counts, mask pattern structure 820A has about 0% of deformation; mask pattern structure 820B has about 2% of deformation; and mask pattern structure 820C has about 10% of deformation. In some embodiments, based on a simulation after 102,200 movement counts, mask pattern structure 820A has about 0.1% of deformation; mask pattern structure 820B has about 8% of deformation; and mask pattern structure 820C has about 20% of deformation. According to these examples and simulation results, the inclusion of lower insulation portion 822a and upper insulation portion 822b further improves the life of mask pattern structure.

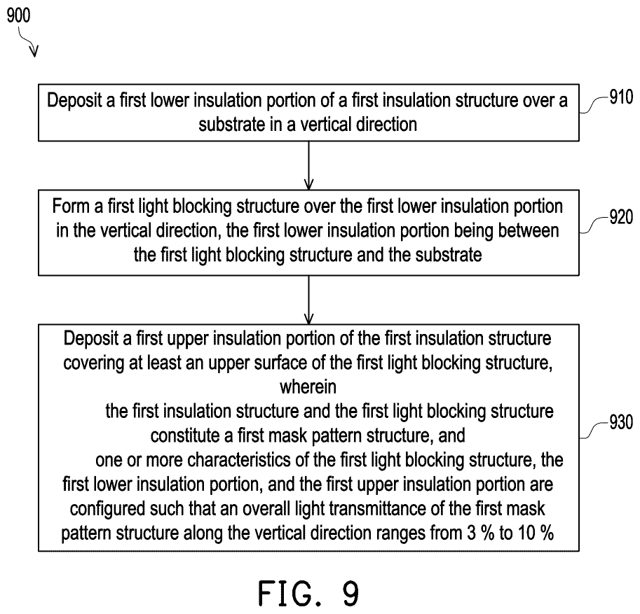

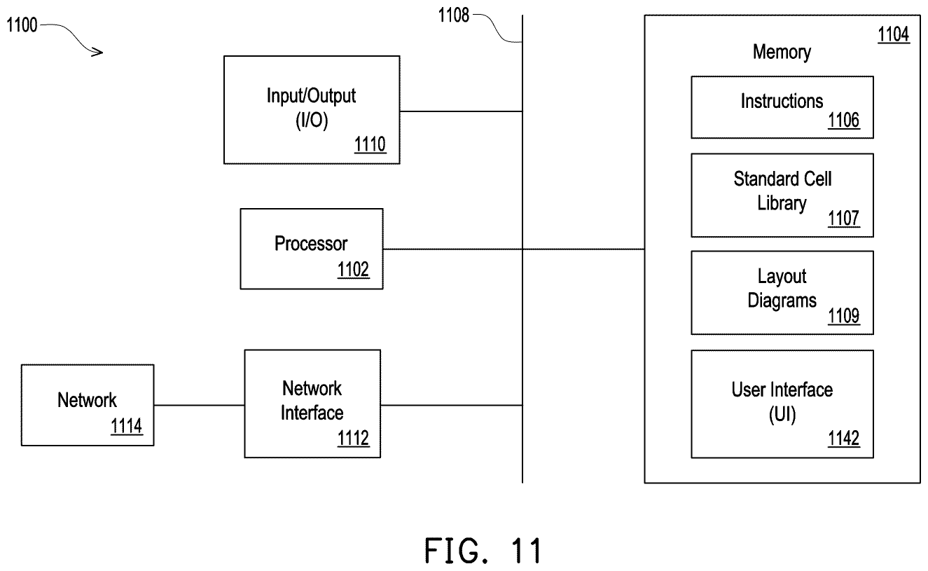

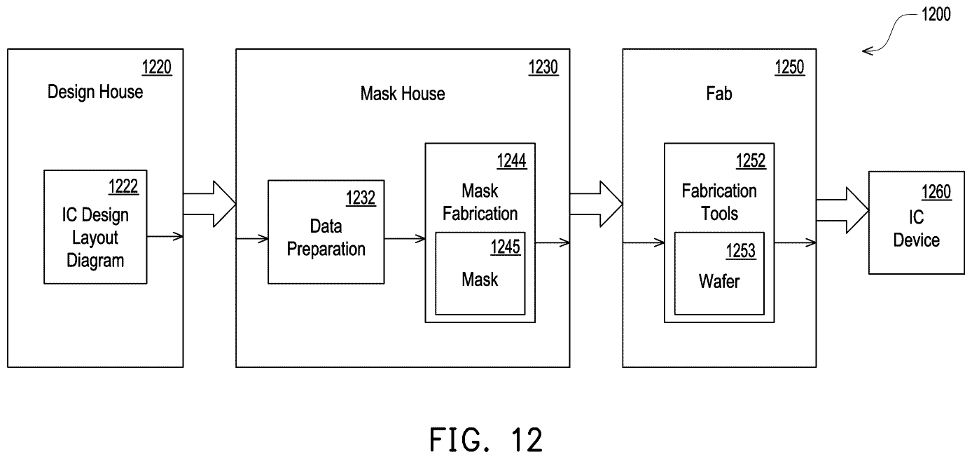

FIG. 9 is a flowchart of a method 900 of manufacturing a photomask, in accordance with some embodiments. In some embodiments, various operations of method 900 correspond to manufacturing the photomask that includes mask pattern structures based on the examples in FIGS. 3A-3D and FIGS. 4A-4C. In some embodiments, the mask pattern structures in method 800 correspond to one or more layout patterns based on an EDA system 1100 as illustrated in FIG. 11. In some embodiments, method 900 corresponds to one or more operations performed based on, in whole or in part, an integrated circuit (IC) manufacturing system 1200 as illustrated in FIG. 12. In FIG. 9, method 900 includes blocks 910-930.

At block 910, a first lower insulation portion (e.g., lower insulation portion 322a in FIG. 3B) of a first insulation structure is deposited over a substrate in a vertical direction (e.g., the Z direction in FIG. 3B). In some embodiments, block 910 corresponds to forming structure 400A in FIG. 4A.

At block 920, a first light blocking structure (e.g., light blocking structure 326 in FIG. 3B) is formed over the first lower insulation portion in the vertical direction. In this non-limiting example, the first lower insulation portion is between the first light blocking structure and the substrate. In some embodiments, block 920 corresponds to forming structure 400B in FIG. 4B.

At block 930, a first upper insulation portion (e.g., upper insulation portion 322b in FIG. 3B) of the first insulation structure is deposited covering at least an upper surface of the first light blocking structure. In some embodiments, block 930 corresponds to forming structure 400C in FIG. 4C. In some embodiments, the first insulation structure and the first light blocking structure constitute a first mask pattern structure (e.g., mask pattern structure 320 in FIG. 3B). In some embodiments, one or more characteristics of the first light blocking structure, the first lower insulation portion, and the first upper insulation portion are configured such that an overall light transmittance of the first mask pattern structure along the vertical direction ranges from 3% to 10%. In some embodiments, the first lower insulation portion and the first upper insulation portion are deposited to cause encapsulation of the first light blocking structure by the first insulation structure.

In some embodiments, the first light blocking structure is formed such that the first light blocking structure has a first thickness (e.g., H1 in FIG. 3B) along the vertical direction. In some embodiments, the first thickness ranges from 40 nm to 80 nm. In some embodiments, the first lower insulation portion is formed such that the first lower insulation portion has a second thickness (e.g., H2 in FIG. 3B) along the vertical direction, and the first upper insulation portion comprises is formed such that the first upper insulation portion has a third thickness (e.g., H3 in FIG. 3B) along the vertical direction. In some embodiments, a ratio of the first thickness to a summation of the second thickness and the third thickness ranges from 6:1 to 3:1.

In some embodiments, the first light blocking structure is formed based on a metal material, an oxide of the metal material, or a combination thereof. In some embodiments, the metal material includes chromium. In some embodiments, the first insulation structure is formed based on silicon dioxide. In some embodiments, the substrate includes a quartz glass.

In some embodiments, method 900 further includes depositing a second lower insulation portion (e.g., lower insulation portion 332a in FIG. 3B) of a second insulation structure over the substrate in the vertical direction, forming a second light blocking structure (e.g., light blocking structure 336 in FIG. 3B) over the second lower insulation portion in the vertical direction, and depositing a second upper insulation portion (e.g., upper insulation portion 332b in FIG. 3B) of the second insulation structure covering at least an upper surface of the second light blocking structure. In this example, the second lower insulation portion is between the second light blocking structure and the substrate, and the second insulation structure and the second light blocking structure constitute a second mask pattern structure (e.g., mask pattern structure 330).

In some embodiments, method 900 further includes forming a third light blocking structure over the substrate in the vertical direction. In this example, the third light blocking structure constitutes a third mask pattern structure (e.g., mask pattern structure 340 in FIG. 3D). In some embodiments, the third light blocking structure includes a molybdenum silicide compound.

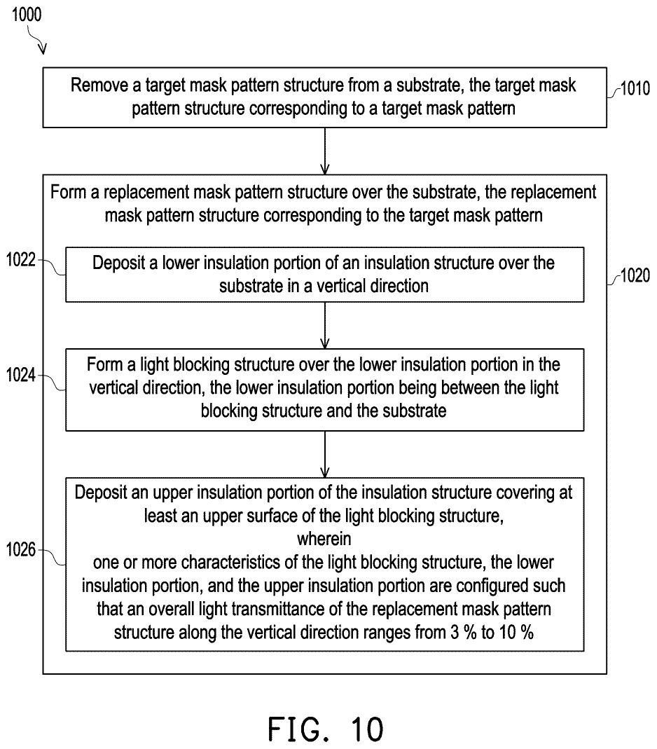

FIG. 10 is a flowchart of a method 1000 of repairing a photomask, in accordance with some embodiments. In some embodiments, various operations of method 1000 correspond to repairing the photomask that includes mask pattern structures based on the examples in FIGS. 3A-3D and FIGS. 5A-5D. In some embodiments, the mask pattern structures in method 1000 correspond to one or more layout patterns based on an EDA system 1100 as illustrated in FIG. 11. In some embodiments, method 1000 corresponds to one or more operations performed based on, in whole or in part, an integrated circuit (IC) manufacturing system 1200 as illustrated in FIG. 12. In FIG. 10, method 1000 includes blocks 1010 and 1020, and block 1020 includes blocks 1022-1026.

At block 1010, a target mask pattern structure (e.g., target mask pattern structure 510 in FIG. 5A) is removed from a substrate. In some embodiments, the target mask pattern structure corresponds. In some embodiments, block 1010 corresponds to forming structure 500A in FIG. 5A.

At block 1020, a replacement mask pattern structure (e.g., mask pattern structure 320 in FIG. 5D) is over the substrate. In some embodiments, the replacement mask pattern structure corresponds to the target mask pattern. In FIG. 10, block 1020 regarding forming the replacement mask pattern structure further includes blocks 1022-1026.

At block 1022, a lower insulation portion (e.g., lower insulation portion 322a in FIG. 3D) of an insulation structure is deposited over a substrate in a vertical direction (e.g., the Z direction in FIG. 3D). In some embodiments, block 1022 corresponds to forming structure 500B in FIG. 5B.

At block 1024, a light blocking structure (e.g., light blocking structure 326 in FIG. 3D) is formed over the lower insulation portion in the vertical direction. In this non-limiting example, the lower insulation portion is between the light blocking structure and the substrate. In some embodiments, block 1024 corresponds to forming structure 500C in FIG. 5C.

At block 1026, an upper insulation portion (e.g., upper insulation portion 322b in FIG. 3D) of the insulation structure is deposited covering at least an upper surface of the light blocking structure. In some embodiments, block 1026 corresponds to forming structure 500D in FIG. 5D. In some embodiments, the insulation structure and the light blocking structure constitute the replacement mask pattern structure (e.g., mask pattern structure 320 in FIG. 3D). In some embodiments, one or more characteristics of the light blocking structure, the lower insulation portion, and the upper insulation portion are configured such that an overall light transmittance of the replacement mask pattern structure along the vertical direction ranges from 3% to 10%. In some embodiments, the lower insulation portion and the upper insulation portion are deposited to cause encapsulation of the first light blocking structure by the insulation structure.

In some embodiments, the light blocking structure is formed such that the light blocking structure has a first thickness (e.g., H1 in FIG. 3D) along the vertical direction. In some embodiments, the first thickness ranging from 40 nm to 80 nm. In some embodiments, the lower insulation portion is formed such that the lower insulation portion has a second thickness (e.g., H2 in FIG. 3D) along the vertical direction, and the upper insulation portion comprises is formed such that the upper insulation portion has a third thickness (e.g., H3 in FIG. 3B) along the vertical direction. In some embodiments, a ratio of the first thickness to a summation of the second thickness and the third thickness ranges from 6:1 to 3:1.

In some embodiments, the light blocking structure is formed based on a metal material, an oxide of the metal material, or a combination thereof. In some embodiments, the metal material includes chromium. In some embodiments, the insulation structure is formed based on silicon dioxide. In some embodiments, the substrate includes a quartz glass.

FIG. 11 is a block diagram of an EDA system 1100, in accordance with some embodiments. In some embodiments, EDA system 1100 includes an automatic placement and routing (APR) system. Methods described herein regarding placement of layout cells are implementable, for example, using EDA system 1100, in accordance with some embodiments.

In some embodiments, EDA system 1100 is a general purpose computing device including a hardware processor 1102 and a memory 1104 that includes a non-transitory, computer-readable storage medium. Memory 1104, amongst other things, is encoded with, i.e., stores, computer program code 1106, i.e., a set of executable instructions. Execution of instructions 1106 by hardware processor 1102 represents (at least in part) an EDA tool which implements a portion or all of the methods described herein in accordance with one or more embodiments (hereinafter, the noted processes and/or methods).

Processor 1102 is electrically coupled to memory 1104 via a bus 1108. Processor 1102 is also electrically coupled to an I/O interface 1110 by bus 1108. A network interface 1112 is also electrically connected to processor 1102 via bus 1108. Network interface 1112 is connected to a network 1114, so that processor 1102 and memory 1104 are capable of connecting to external elements via network 1114. Processor 1102 is configured to execute computer program code 1106 encoded in memory 1104 in order to cause system 1100 to be usable for performing a portion or all of the noted processes and/or methods. In one or more embodiments, processor 1102 is a central processing unit (CPU), a multi-processor, a distributed processing system, an application specific integrated circuit (ASIC), and/or a suitable processing unit.

In one or more embodiments, memory 1104 is an electronic, magnetic, optical, electromagnetic, infrared, and/or a semiconductor system (or apparatus or device). For example, memory 1104 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 1104 includes a compact disk-read only memory (CD-ROM), a compact disk-read/write (CD-R/W), and/or a digital video disc (DVD).

In one or more embodiments, memory 1104 stores computer program code 1106 configured to cause system 1100 (where such execution represents (at least in part) the EDA tool) to be usable for performing a portion or all of the noted processes and/or methods. In one or more embodiments, memory 1104 also stores information which facilitates performing a portion or all of the noted processes and/or methods. In one or more embodiments, memory 1104 stores standard cell library 1107 of standard cells including such standard cells as disclosed herein. In one or more embodiments, memory 1104 stores one or more layout diagrams 1109 corresponding to one or more layouts disclosed herein.

EDA system 1100 includes I/O interface 1110. I/O interface 1110 is coupled to external circuitry. In one or more embodiments, I/O interface 1110 includes a keyboard, keypad, mouse, trackball, trackpad, touchscreen, and/or cursor direction keys for communicating information and commands to processor 1102. In at least one embodiment, EDA system 1100 does not include I/O interface 1110.

EDA system 1100 also includes network interface 1112 coupled to processor 1102. Network interface 1112 allows system 1100 to communicate with network 1114, to which one or more other computer systems are connected. Network interface 1112 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1100.

System 1100 is configured to receive information through I/O interface 1110. The information received through I/O interface 1110 includes one or more of instructions, data, design rules, libraries of standard cells, and/or other parameters for processing by processor 1102. The information is transferred to processor 1102 via bus 1108. EDA system 1100 is configured to receive information related to a UI through I/O interface 1110. The information is stored in memory 1104 as user interface (UI) 1142.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 12 is a block diagram of an integrated circuit (IC) manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1200.

In FIG. 12, IC manufacturing system 1200 includes entities, such as a design house 1220, a mask house 1230, and an IC manufacturer/fabricator (fab) 1650, that interact with one another in the design, development, and manufacturing cycles and/or services related to manufacturing an IC device 1260. The entities in system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1220, mask house 1230, and IC fab 1250 is owned by a single larger company. In some embodiments, two or more of design house 1220, mask house 1230, and IC fab 1250 coexist in a common facility and use common resources.

Design house (or design team) 1220 generates an IC design layout diagram 1222. IC design layout diagram 1222 includes various geometrical patterns designed for an IC device 1260. The geometrical patterns correspond to patterns of metal, oxide, or semiconductor layers that make up the various components of IC device 1260 to be fabricated. The various layers combine to form various IC features. For example, a portion of IC design layout diagram 1222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1220 implements a proper design procedure to form IC design layout diagram 1222. The design procedure includes one or more of logic design, physical design or place and route. IC design layout diagram 1222 is presented in one or more data files having information of the geometrical patterns. For example, IC design layout diagram 1222 can be expressed in a GDSII file format or DFII file format.

Mask house 1230 includes data preparation 1232 and mask fabrication 1244. Mask house 1230 uses IC design layout diagram 1222 to manufacture one or more masks 1245 (e.g., photomasks based on one or more embodiments in this disclosure) to be used for fabricating the various layers of IC device 1260 according to IC design layout diagram 1222. Mask house 1230 performs mask data preparation 1232, where IC design layout diagram 1222 is translated into a representative data file (RDF). Mask data preparation 1232 provides the RDF to mask fabrication 1244. Mask fabrication 1244 includes a mask writer. A mask writer converts the RDF to an image on a substrate, such as a mask (reticle) 1245 or a semiconductor wafer 1253. The design layout diagram 1222 is manipulated by mask data preparation 1232 to comply with particular characteristics of the mask writer and/or requirements of IC fab 1250. In FIG. 12, mask data preparation 1232 and mask fabrication 1244 are illustrated as separate elements. In some embodiments, mask data preparation 1232 and mask fabrication 1244 can be collectively referred to as mask data preparation.

In some embodiments, mask data preparation 1232 includes optical proximity correction (OPC) which uses lithography enhancement techniques to compensate for image errors, such as those that can arise from diffraction, interference, other process effects and the like. OPC adjusts IC design layout diagram 1222. In some embodiments, mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1232 includes a mask rule checker (MRC) that checks the IC design layout diagram 1222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1222 to compensate for photolithographic implementation effects during mask fabrication 1244, which may undo part of the modifications performed by OPC in order to meet mask creation rules.

In some embodiments, mask data preparation 1232 includes lithography process checking (LPC) that simulates processing that will be implemented by IC fab 1250 to fabricate IC device 1260. LPC simulates this processing based on IC design layout diagram 1222 to create a simulated manufactured device, such as IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1222.

It should be understood that the above description of mask data preparation 1232 has been simplified for the purposes of clarity. In some embodiments, data preparation 1232 includes additional features such as a logic operation (LOP) to modify the IC design layout diagram 1222 according to manufacturing rules. Additionally, the processes applied to IC design layout diagram 1222 during data preparation 1232 may be executed in a variety of different orders.

After mask data preparation 1232 and during mask fabrication 1244, a mask 1245 or a group of masks 1245 are fabricated based on the modified IC design layout diagram 1222. In some embodiments, mask fabrication 1244 includes performing one or more lithographic exposures based on IC design layout diagram 1222. In some embodiments, an electron-beam (e-beam) or a mechanism of multiple e-beams is used to form a pattern on a mask (photomask or reticle) 1245 based on the modified IC design layout diagram 1222. Mask 1245 can be formed in various technologies (e.g., based on one or more embodiments in this disclosure). In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. The mask(s) generated by mask fabrication 1244 is used in a variety of processes. For example, such a mask(s) is used in an ion implantation process to form various doped regions in semiconductor wafer 1253, in an etching process to form various etching regions in semiconductor wafer 1253, and/or in other suitable processes.

IC fab 1250 is an IC fabrication business that includes one or more manufacturing facilities for the fabrication of a variety of different IC products. In some embodiments, IC fab 1250 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1250 includes fabrication tools 1252 configured to execute various manufacturing operations on semiconductor wafer 1253 such that IC device 1260 is fabricated in accordance with the mask(s), e.g., mask 1245. In various embodiments, fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1250 uses mask(s) 1245 fabricated by mask house 1230 to fabricate IC device 1260. Thus, IC fab 1250 at least indirectly uses IC design layout diagram 1222 to fabricate IC device 1260. In some embodiments, semiconductor wafer 1253 is fabricated by IC fab 1250 using mask(s) 1245 to form IC device 1260. In some embodiments, the IC fabrication includes performing one or more lithographic exposures based at least indirectly on IC design layout diagram 1222. Semiconductor wafer 1253 includes a silicon substrate or other proper substrate having material layers formed thereon. Semiconductor wafer 1253 further includes one or more of various doped regions, dielectric features, multilevel interconnects, and the like (formed at subsequent manufacturing steps).

In some aspects, a method of manufacturing a photomask includes depositing a first lower insulation portion of a first insulation structure over a substrate in a vertical direction; forming a first light blocking structure over the first lower insulation portion in the vertical direction, the first lower insulation portion being between the first light blocking structure and the substrate; and depositing a first upper insulation portion of the first insulation structure covering at least an upper surface of the first light blocking structure. The first insulation structure and the first light blocking structure constitute a first mask pattern structure. One or more characteristics of the first light blocking structure, the first lower insulation portion, and the first upper insulation portion are configured such that an overall light transmittance of the first mask pattern structure along the vertical direction ranges from 3% to 10%.

In some aspects, a photomask includes a substrate and a first mask pattern structure. The first mask pattern structure includes a first light blocking structure over the substrate in a vertical direction, and a first insulation structure over the substrate in the vertical direction. The first insulation structure includes a first lower insulation portion and a first upper insulation portion. The first lower insulation portion is between the first light blocking structure and the substrate, and the first upper insulation portion covers at least an upper surface of the first light blocking structure. An overall light transmittance of the first mask pattern structure along the vertical direction ranges from 3% to 10%.

In some aspects, a method of repairing a photomask includes removing a target mask pattern structure from a substrate, the target mask pattern structure corresponding to a target mask pattern; and forming a replacement mask pattern structure over the substrate, the replacement mask pattern structure corresponding to the target mask pattern. Forming the replacement mask pattern structure includes depositing a lower insulation portion of an insulation structure over the substrate in a vertical direction; forming a light blocking structure over the lower insulation portion in the vertical direction, the lower insulation portion being between the light blocking structure and the substrate; and depositing an upper insulation portion of the insulation structure covering at least an upper surface of the light blocking structure. One or more characteristics of the light blocking structure, the lower insulation portion, and the upper insulation portion are configured such that an overall light transmittance of the replacement mask pattern structure along the vertical direction ranges from 3% to 10%.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

1. A method of manufacturing a photomask, the method comprising:
depositing a first lower insulation portion of a first insulation structure over a substrate in a vertical direction;
forming a first light blocking structure over the first lower insulation portion in the vertical direction, the first lower insulation portion being between the first light blocking structure and the substrate; and
depositing a first upper insulation portion of the first insulation structure covering at least an upper surface of the first light blocking structure,
wherein
the first insulation structure and the first light blocking structure constitute a first mask pattern structure, and
one or more characteristics of the first light blocking structure, the first lower insulation portion, and the first upper insulation portion are configured such that an overall light transmittance of the first mask pattern structure along the vertical direction ranges from 3% to 10%.

2. The method of claim 1, wherein
the depositing the first lower insulation portion and the depositing the first upper insulation portion are performed to cause encapsulation of the first light blocking structure by the first insulation structure.

3. The method of claim 1, wherein
the forming the first light blocking structure comprises forming the first light blocking structure having a first thickness along the vertical direction, and the first thickness ranging from 40 nanometers (nm) to 80 nm.

4. The method of claim 1, wherein
the forming the first light blocking structure comprises forming the first light blocking structure having a first thickness along the vertical direction,
the depositing the first lower insulation portion comprises depositing the first lower insulation portion having a second thickness along the vertical direction,
the depositing the first upper insulation portion comprises depositing the first upper insulation portion having a third thickness along the vertical direction, and
a ratio of the first thickness to a summation of the second thickness and the third thickness ranges from 6:1 to 3:1.

5. The method of claim 1, wherein
the first light blocking structure is formed based on a metal material, an oxide of the metal material, or a combination thereof.

6. The method of claim 5, wherein
the metal material comprises chromium.

7. The method of claim 1, wherein
the first insulation structure is formed based on silicon dioxide.

8. The method of claim 1, wherein
the substrate comprises a quartz glass.

9. The method of claim 1, further comprising:
depositing a second lower insulation portion of a second insulation structure over the substrate in the vertical direction;
forming a second light blocking structure over the second lower insulation portion in the vertical direction, the second lower insulation portion being between the second light blocking structure and the substrate;
depositing a second upper insulation portion of the second insulation structure covering at least an upper surface of the second light blocking structure,
wherein
the second insulation structure and the second light blocking structure constitute a second mask pattern structure.

10. The method of claim 1, further comprising:
forming a third light blocking structure over the substrate in the vertical direction, wherein
the third light blocking structure includes a molybdenum silicide compound, and
the third light blocking structure constitutes a third mask pattern structure.

11. A photomask, comprising:
a substrate; and
a first mask pattern structure, including:
a first light blocking structure over the substrate in a vertical direction, and a first insulation structure over the substrate in the vertical direction, the first insulation structure including a first lower insulation portion and a first upper insulation portion, the first lower insulation portion being between the first light blocking structure and the substrate, and the first upper insulation portion covering at least an upper surface of the first light blocking structure,
wherein
an overall light transmittance of the first mask pattern structure along the vertical direction ranges from 3% to 10%.

12. The photomask of claim 11, wherein
the first lower insulation portion and the first upper insulation portion are configured to cause encapsulation of the first light blocking structure by the first insulation structure.

13. The photomask of claim 11, wherein
the first light blocking structure has a first thickness along the vertical direction, and the first thickness ranging from 40 nanometers (nm) to 80 nm.

14. The photomask of claim 11, wherein
the first light blocking structure has a first thickness along the vertical direction,
the first lower insulation portion has a second thickness along the vertical direction,
the first upper insulation portion has a third thickness along the vertical direction, and
a ratio of the first thickness to a summation of the second thickness and the third thickness ranges from 6:1 to 3:1.

15. The photomask of claim 11, wherein
the first light blocking structure includes a metal material, an oxide of the metal material, or a combination thereof,
the metal material comprises chromium, and
the first insulation structure is formed based on silicon dioxide.

16. The photomask of claim 11, further comprising:
a second mask pattern structure including:
a second light blocking structure over the substrate in the vertical direction, and
a second insulation structure over the substrate in the vertical direction, the second insulation structure including a second lower insulation portion and a second upper insulation portion, the second lower insulation portion being between the second light blocking structure and the substrate, and the second upper insulation portion covering at least an upper surface of the second light blocking structure,
wherein
the second insulation structure encapsulates the second light blocking structure.

17. The photomask of claim 11, further comprising:
a third mask pattern structure including a third light blocking structure over the substrate in the vertical direction, the third light blocking structure including a molybdenum silicide compound.

18. A method of repairing a photomask, the method comprising:
removing a target mask pattern structure from a substrate, the target mask pattern structure corresponding to a target mask pattern; and
forming a replacement mask pattern structure over the substrate, the replacement mask pattern structure corresponding to the target mask pattern, and the forming the replacement mask pattern structure comprises:
depositing a lower insulation portion of an insulation structure over the substrate in a vertical direction;
forming a light blocking structure over the lower insulation portion in the vertical direction, the lower insulation portion being between the light blocking structure and the substrate; and
depositing an upper insulation portion of the insulation structure covering at least an upper surface of the light blocking structure,
wherein
one or more characteristics of the light blocking structure, the lower insulation portion, and the upper insulation portion are configured such that an overall light transmittance of the replacement mask pattern structure along the vertical direction ranges from 3% to 10%.

19. The method of claim 18, wherein
the depositing the lower insulation portion and the depositing the upper insulation portion are performed to cause encapsulation of the light blocking structure by the insulation structure.

20. The method of claim 18, wherein
the forming the light blocking structure comprises forming the light blocking structure having a first thickness along the vertical direction,
the depositing the lower insulation portion comprises depositing the lower insulation portion having a second thickness along the vertical direction,
the depositing the upper insulation portion comprises depositing the upper insulation portion having a third thickness along the vertical direction, and
a ratio of the first thickness to a summation of the second thickness and the third thickness ranges from 6:1 to 3:1.
